(19) United States
(12) Patent Application Publication
(10) Pub. No.: US 2002/0144831 A1
(43) Pub. Date: Oct. 10, 2002

(54) Environmentally green shelter structure for commercial and residential use

(76) Inventor: Charles G. Kalt, Williamstown, MA (US)

Correspondence Address: HANDAL & MOROFSKY, 80 WASHINGTON STREET, NORWALK, CT, 06854, US

(21) Appl. No.: 10/086,187

(22) Filed: Feb. 27, 2002

Related U.S. Application Data
(60) Provisional application No. 60/272,124, filed on Feb. 28, 2001.

(51) Int. Cl. H05K 9/00

(52) U.S. Cl. 174/35 R

(57) ABSTRACT

A window for gating light for the purpose of controlling temperature within a building, comprising a light transmissive substrate, a plurality of at least partially reflective rollout members disposed on said substrate, the rollout members being responsive to a source of electrical potential to cause the rollout members to rollout, and an electrically conductive at least partially light transmissive conductive member disposed in facing relationship with said reflective rollout members and said substrate.

### TECHNICAL FIELD

The present invention relates to buildings having surfaces and/or other features adapted to achieve environmentally green objectives while providing shelter, heat and light.

### BACKGROUND OF THE INVENTION

Modern science has theorized that relatively near the dawn of creation, what was to become our earth, came spinning off from the rotating molten mass of our sun. Since that point, all energy “expanded” on the earth and the light which supports it has been due to solar activity. After the separation of the earth from the sun, with its initial charge of thermal energy the earth continued to receive solar energy in the form of radiation during an initial cooling period in which earth temperatures dropped through because of outgoing thermal radiation. When the outgoing thermal radiation dropped to the point where it substantially equaled incoming radiation from the sun in the form of sunlight, a state of substantial equilibrium (the state in which life was created and has evolved).

Since the time of the first evolution of life, sunlight has fallen upon the Earth to perform two functions. The first is to balance exothermic losses due to radiation emanating from the warm planet Earth into the blackness of space. The second is to transform matter into molecular forms having higher level energy states. Transformed matter may deteriorate via processes such as metabolic activity, decay and combustion, during which they give off the energy stored in them through the action of biological processes fueled by the sun.

As a result of the above processes, vast reserves of coal, oil, and natural gas have been created. These materials fuel substantially all human activity at this time. However, it is universally recognized that consumption of such fuels will, even in the relatively short term, be severely impacted by the eventual depletion of the reserves and pollution of the environment.

For many years, the idea has held sway that direct conversion of solar energy into forms which can be efficiently stored and consumed, combined with direct consumption of solar energy to achieve mechanical objectives of present energy-consuming environmental control systems, will reduce both the problems of depletion and pollution.

Nevertheless, one need only glance about to see the millions of structures built in the last thirty years to see that except for increased use and installation of solar-mechanical systems for the purpose of effecting indoor climate control in shelter structures, both in the commercial and residential fields, structures remain substantially unchanged since the dawn of the industrial age.

In order for so called “green” mechanical strategies to have a substantial impact on current building practice, it is clear that dramatic new technologies must be implemented, and that these technologies must combine effectiveness with practicality and economy.

If present mechanical systems, including heating and air conditioning, are to be replaced, the new systems must be reliable, easy to use and have substantial capacity. The new systems will have to achieve design objectives year round in environments with temperature variations ranging typically about fifty five degrees centigrade between highs and lows.

For many years, many solar energy systems showed the potential of having substantial impact on climate control. Heat absorbing walls, when properly situated, can store huge amounts of heat. Direct heating of spaces and people through the use of solar energy is also relatively effective. Likewise, lighting of spaces with sunlight is also effective. Given the demonstrated capacity of solar systems, it is clear that its effectiveness partially depends on gating strategies.

In some cases gating can be a relatively simple thing to achieve. For example, in the case of solar water-heating systems of the type that comprise a plurality of pipes painted black and placed in insulated housings which admit sunlight for the purpose of it being absorbed by the black pipes to heat water within the black pipes, gating may simply take the form of turning a water circulation pump on and off. Systems for heating water, such as the one discussed above, have seen relatively wide employment.

Conversely, systems utilizing sunlight directly to warm room spaces or walls designed to store heat have seen very little employment because of the necessity for human involvement in the form of opening and closing blinds, and the like. While in principle the rules for doing this are relatively straightforward, actual effective implementation of such rules involves making judgments and continual practices not normally performed or found desirable to be performed by people.

For example, blinds, during the winter, must be opened up early in the morning as soon as the sun rises. As soon as the sun goes down, the blinds must be closed to retain thermal energy and prevent it from being radiated outside through the windows controlled by the blind system. Of course, sunrise and sunset times vary everyday and cloud cover will complicate the problem. The gravity of the problem increases with the capacity of the system. In other words, the larger the windows admitting sunlight energy the more important it is to conserve that energy at night when the window functions, effectively, as a very large hole gradually leaking, into the darkness of space, the energy from the sun collected during the day. Likewise, in the case of windows facing in, for example, eastern and western directions in the northern United States, decisions must be made with respect to relative advantage and disadvantage of having both or either of the systems in an open or closed state.

Present systems for gating sunlight generally comprise mechanical members driven by motors which, for example, roll and unroll a reflective material. Such systems suffer from numerous drawbacks. Motors are expensive, tend to wear out, and are difficult to replace. Such systems have not achieved widespread acceptance because consumers are accustomed to receiving extremely long life from current window systems and the same cannot be achieved with motorized solar gates.

In addition, reliability is an issue also having an adverse impact on consumer acceptance.

In addition systems break down from various causes. Starting and stopping electrical motors can be extremely wearing.

Even under normal operation, motors themselves generally work with commutators and brushes which involve constantly opening and closing electrical circuits as the motor is rotated. The starting and stopping of the motor causes severe transient forces on the mechanical gating members and this problem is complicated due to frictional forces on the gating members and other elements in the system. The overall result is a system which is substantially unacceptable to the consumer and has seen only de minimis implementation.

About thirty years ago, in my U.S. Pat. No. 3,989,357, I proposed the idea that a plastic film coated with a reflective material such as aluminum could be used to control the reflection of light. Shortly thereafter, in U.S. Pat. No. 4,094,590, I proposed that such reflectivity could be achieved in the context of a tightly rolled plastic sheet which naturally tended to assume the rolled configuration, and which could be unfurled electrostatically through the use of static electricity. In this patent, I also noted that this system could be used to control solar light. However, such systems have not seen commercialization. Effective commercialization has been prevented due to the absence of structures which can be manufactured at an economically feasible cost, while retaining system performance.

### SUMMARY OF THE INVENTION

In accordance with the preferred embodiment of the invention, the gating of solar energy is provided using a plurality of plastic film reflectors. Each reflector comprises a flat planar sheet of plastic which has been formed into a tight roll. The planar sheet of plastic has a layer of a conductive material deposited on it. In accordance with the preferred embodiment of the invention, the reflective material is a layer of aluminum which gives the reflective member its reflective characteristic. Typically, a plurality of such coiled up reflective members would be mounted on a large window and, when actuated, may be unrolled through the use of static electricity thus causing them to cover their respective portions of a window member on which they are mounted.

In a typical application, a plurality of mirror like roll out members are disposed on a clear transparent member which functions as a window. When no voltage is applied to the system, the rollout is substantially coiled and the system is essentially optically open. When a voltage is applied, each of the rollout electrodes is caused to unroll and cover clear surfaces of the window. If desired, all of the roll-outs may be actuated or only some of the roll-outs may be actuated to achieve a variable amount of transmission of light through the window.

Rollout is achieved through the use of a transparent conductive substrate which is deposited on the clear transparent member which is to serve as a window. A voltage potential difference is applied to the rollout electrode and the substrate. The application of, for example, opposite electrical voltages to these two members causes the rollout electrode to be attracted to the substrate thus causing the rollout electrode to unfurl and cover the previously clear surface of the transparent member with a reflective material.

Such rollout is achieved because of the attraction between the electrically charged rollout electrode and the transparent substrate. Thus, when the electrode is rolled out, the surface on which it is disposed appears reflective and thus, will prevent external light, such as sunshine from entering the structure, while, also preventing light and other radiant energy within the structure from escaping through what would otherwise be a transparent window. Thus, at night, the rollout electrodes would be actuated to reduce losses of thermal energy from inside a structure by closing the structure optically. This would prevent excessive cooling of a building during the winter and during the summer on relatively cold summer nights. During the day, during the winter, it is likely that roll-outs would be left in their retracted light transmitting positions to allow sunlight to enter the building to heat up the spaces inside the building, and perhaps, to heat up certain walls or other structures designed to absorb and store radiant energy.

On the other hand, during the summer, during the daylight hours, it is more advantageous to prevent the entry of ambient energy into the structure.

Accordingly, the rollout electrodes would be put in their actuated state, optically blocking the transparent surface of the window with a reflective member or more precisely a matrix of reflective members, whose function is to exclude introduction of sunlight into the system, which would otherwise tend to increase the temperature of the space inside the structure.

More particularly, in accordance with the invention, a window for gating light for the purpose of controlling temperature within a building, comprising a light transmissive substrate, a plurality of at least partially reflective rollout members disposed on the substrate, and an electrically conductive at least partially light transmissive conductive member disposed in facing relationship with the reflective rollout members and the substrate, a source of electrical potential for causing the rollout members to rollout, conductors for coupling the source of electrical potential to the rollout members and the at least partially light transmissive conductive member, the at least partially light transmissive conductive member being electrically insulated from the rollout's.

The at least partially light transmissive conductive member is disposed between the rollout and the substrate. The rollouts may be individually rolled out, or rolled out in groups comprising less than all of the rollouts on the window. In accordance with the invention, such a window is employed in a building comprising a plurality of such windows.

Such a building would have a plurality of sides, each of the sides having a plurality of such windows disposed on each side, and further comprising a control system, the control system operative to vary the passage of light through windows on one side of the building to be different from the passage of light through windows on other sides of the building. This control system would have a plurality of environmental conditions sensors; a central processing unit; a first computer storage medium portion with a weather protection algorithm recorded on the computer storage medium; a second computer storage medium portion with user desired internal building environmental conditions recorded thereon; a third computer storage medium portion with weather prediction information stored thereon; a fourth computer storage medium portion with a system model of the building and its heating and cooling characteristic stored thereon; switches coupled to the central processing unit for controlling heating and/or cooling and/or humidifier/dehumidifier systems; and a plurality of drivers for driving the rollouts on the windows. The sensors comprise an outside temperature sensor, an inside temperature sensor, an outside windspeed sensor, an outside humidity sensor, and inside humidity sensor, a shade light sensor, a sunlight sensor, and a pressure sensor.

In accordance with the inventive method for controlling an environmental system in the building, several steps are employed. Such steps include reading current conditions within a building and outside a building. The system predicts future outside environmental conditions and determines whether current conditions within a building are helpful for accommodating future changes in the outside environment of the building. In the event that such conditions are deemed helpful, the system assesses system capacities and decides upon a system actuation time and actuates appropriate mechanical systems in response. The system then implements a timeout interval before actuation of the system or actuation of the system in response to a period change within certain user set input conditions. In the event that conditions are found helpful, determining whether the deviation caused by using the conditions is helpful. In the event that conditions are not found helpful, the system calculates utilization potential, decides upon system actuation time and actuates mechanical systems after which the system is advanced to the timeout interval.

Other objects and advantages of the invention will be evident from the following detailed description when read in conjunction with the accompanying drawings which depict illustrative embodiments of the invention.

### BRIEF DESCRIPTION OF THE DRAWINGS

Further objects, features, and advantages of the present invention will become apparent upon consideration of the detailed description of the presently-preferred embodiments, when taken in conjunction with the accompanying drawings. It is noted, however, that the appended drawings illustrate only a typical embodiment of this invention and is therefore not to be considered limiting of its scope, for the invention may admit to other equally effective embodiments. Reference the appended drawings, wherein:

FIG. 1 depicts a front view of an embodiment of a window panel constructed in accordance with the present invention;

FIG. 2 is a cross sectional view of one inventive panel when no electricity is applied to the system;

FIG. 3 is a cross sectional view of one inventive panel when electricity is applied to the system;

FIG. 4 is a cross sectional view of another embodiment of an inventive panel employed on double glazed window, when no electricity is applied to the system;

FIG. 5 illustrates another embodiment of the inventive panel having length-wise rollouts.

FIG. 6 illustrates a plurality of inventive window panels for use in a structure;

FIG. 7 illustrates a structure employing the inventive window panels;

FIG. 8 is a flow diagram illustrating a control system for use with the present invention; and,

FIG. 9 is a flow diagram illustrating one aspect of the inventive method for controlling mechanical systems to achieve specified environmental ranges inside a building.

### DETAILED DESCRIPTION OF THE PREFERRED EMBODIMENT

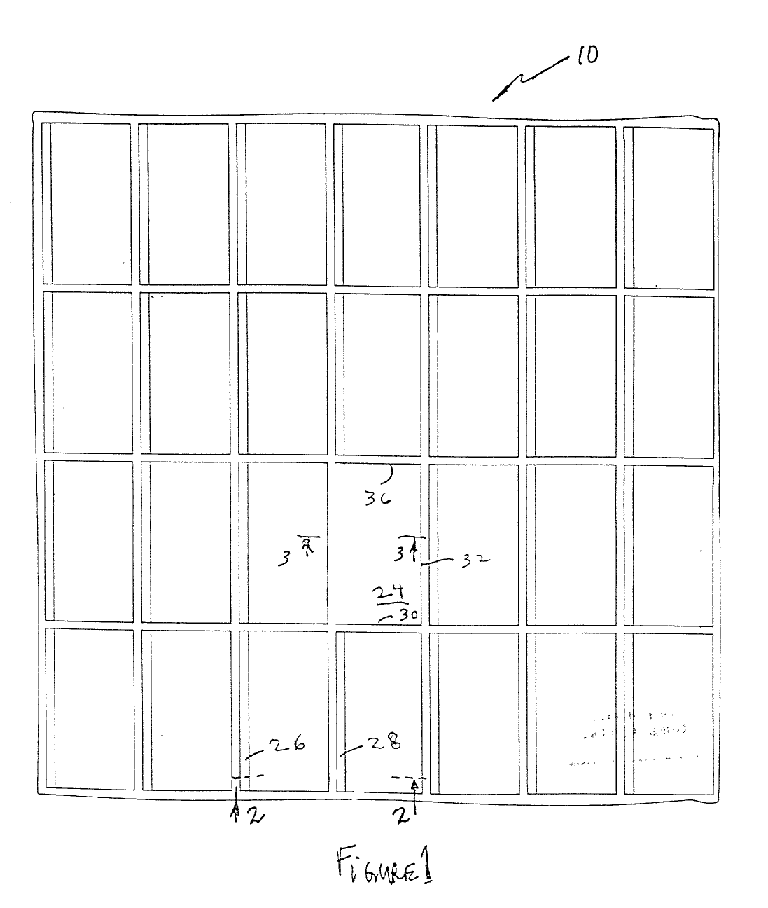

Referring to FIG. 1, in accordance with the present invention radiant energy entering and/or exiting the building through windows is gated by an electrostatic window panel 10. Panel 10 comprises a glass or plastic substrate 12. Substrate 12 is transparent and is the main structural element of the panel. In accordance with the invention, it is contemplated that substrate 12 with the other elements of panel 10, as will be described fully below, will function as a replacement for one of the glass panes in a single, double or triple glazed window.

In particular, with reference to FIGS. 1-3, a layer 14 of electrically conductive transparent material is deposited over substrate 12. Layer 14 may be made of any suitable material, such as indium tin oxide (ITO). ITO layer 14 is secured to substrate 12. An insulative layer 16 is disposed over and secured to ITO layer 14. Insulative layer 16 is made of any suitable insulative material, such as plastic, although wide variety of possible materials exist including such diverse materials as shellac, varnish, sputter deposited glass, and so forth. A rollout layer 18 is positioned over layer 16. Layer 18 comprises a plastic structural member 20 and a layer of metal 22 which is secured to plastic layer 20. Layer 18 may be made from conventional metallized mylar, or any other suitable material. Rollouts, such as rollout 24, which is in the unfurled state, and rolled up rollouts 26 and 28, are defined within rollout layer 18 by cuts 30, 32 and 36. Cutting along cuts 30, 32 and 36 generally defines a tongue which forms a rollout, as is illustrated most clearly with respect to rollout 24 in FIG. 1.

Rollout 24 is an example of a rollout in the excited state, that is with electricity applied to the system, as will be described below. When no electricity is applied to the system it is desired that the rollout take a rolled up configuration as is illustrated in the case of rollouts 26 and 28,. Generally, causing a top to form a coiled rolled up rollout, such as rollout 24 is done by putting the same in an oven, heating it and thus causing the plastic portion of the top to shrink. Because the metallized layer of metal 22 does not shrink when it is heated, the result is the naturally coiled rollout 24. When it is desired to unfurl rollout 24, electrical potential must be applied to the system, as will be described below. The result is an unfurled electrode such as rollout 24.

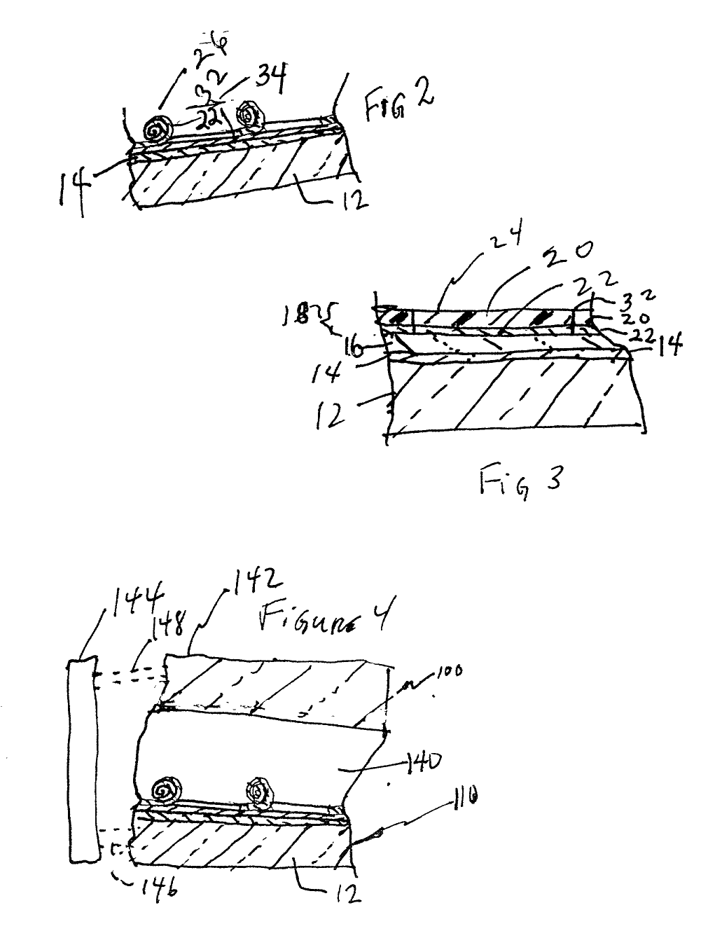

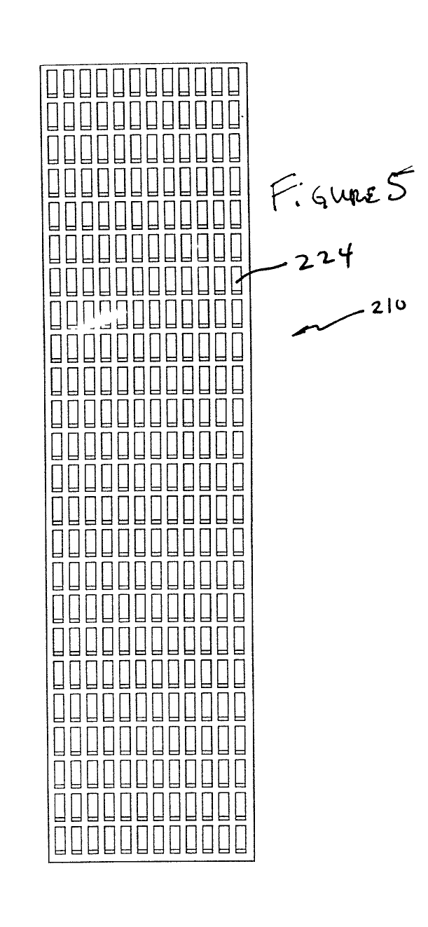

When it is decided to unfurl an electrode, such as electrode 26 in FIG. 2, electrical potential is applied between transparent conductive layer 14 and the layer of metal 22 in rollout 26, as illustrated in FIG. 2. The result is an attraction between layer of metal 22 and transparent conductive layer 14, resulting in the rolled off rollout 26 being pulled in the direction indicated by arrow 34, as indicated in FIG. 2. When rollout 26 has been completely unrolled, it is flat and thus appears like rollout 24 in FIGS. 1 and 3.

In accordance with the invention, an entire panel comprising a substitute for a glass pane will incorporate the rollout cells such as those illustrated in FIG. 1. Thus, while FIG. 1 shows only a portion of a panel 10 constructed in accordance with the present invention, it is understood that the entire surface of a window pane substitute will be covered by rollouts.

In accordance with preferred invention, it is contemplated that the metal coating 22 on each rollout will be at least 90 percent reflective. While this means that gating efficiency may be only 90 percent, it also means that the remaining 10 percent of the light (outside of the building on which the window incorporating the inventive panel is installed) will pass through to the inside of the building, even when the gates are closed, thus providing a 10 percent view of the landscape outside the window. This prevents a feeling of claustrophobia, and promotes a sense of wellbeing for occupants within the building.

It is also contemplated in accordance with the present invention that reflective layer of metal 22 may be replaced by material having filtering characteristics. More physically, instead of a layer of metal 22, metal 22 may be replaced by a filtering material or filtering structure which has the effect of passing visible light, while reflecting harmful ultraviolet and heating infrared wavelengths. This would have the effect of providing a building with visible wavelengths of light for the purpose of performing ordinary tasks, while blocking, for example, infrared light which would have the undesirable effect, in the summertime, of heating the inside of the building, and thus increasing the load on air conditioning mechanical systems.

Such a structure, during the wintertime, would have no effect, insofar as, during cold weather, it is advantageous for the inventive system to be open during the day, allowing sunlight into a room for the purpose of heating the inside of the room, or to heat a structure provided in the room for the purpose of absorbing radiant energy for later release at night.

In the event that one wishes to use a filtering structure, this filtering structure must be inherently conductive, for conductive structure must be added to the rollout. This may be done by intermittent, for example striped, application of conductive material. In accordance with the preferred embodiment, the strips of conductive material extend parallel to the direction of rollout, so that coiling of the structure will occur during heating of the structure. This process is described more fully below.

In accordance with the preferred embodiment of the invention, it is contemplated that each light-gating panel will be constructed from a single substrate member 12, which is coated with a transparent conductive material to form layer 14, and coated with an insulative material to form layer 16. A single sheet of metallized plastic would then be selectively applied to the panel. A laser or knife may then be used to cut out the rollout members. After the same is heated in an oven, the rollouts take a rolled up configuration because of the natural tendency of the plastic to shrink while the metallized layer retains its original dimension.

Once a structure has been so constructed, it is necessary to provide means for applying a voltage potential between the metal layer 22 and the conductive layer of indium tin oxide 14. This may simply take the form of spot welding a pair of leads to the panel 10, one only to be welded to the metal layer 22, and the other lead being electrically attached to the indium tin oxide layer 14. Attachment to the indium tin oxide layer 14 may be made by laying down a conductive layer over a small portion of substrate 12, and then depositing the indium tin oxide layer 14 over the conductive layer.

The construction of the above described structure may use methods and materials such as those detailed in part in U.S. Pat. Nos. 4,488,784, 5,231,559, 5,519,565, 5,638,084 and 6,057,814, the entire disclosures of which are hereby incorporated herein by reference thereto. Moreover, the particular method described in that application will result in a panel which has individually addressable rollouts. Thus video information may be sent to each panel and the panel may be made to display advertising or other visual information. In addition, is desired, all of the panels on the side of the building may be used in cooperation to send a high density of video information to the public for the purpose of advertising, community service, or the like.

Such a structure will have the characteristic of being actuatable as a single unit, that is it would result in making a panel which may be used to completely open or to close a window, because all of the rollouts on the panel will be actuated simultaneously, or have their voltage potential removed from them simultaneously.

Alternatively, application of a proper signal as a voltage potential to such a window can result in partial rollout of one of the rollouts, resulting in a proportional control of the amount of light passing through the system.

In any case, it is noted that the use of a large number of rollouts on a single panel is particularly advantageous, because the same may be quickly actuated. Likewise, because of the small size of the individual rollouts, the likelihood of mechanical failure is minimized. Moreover, in the event of such a failure, it would be limited to a single cell.

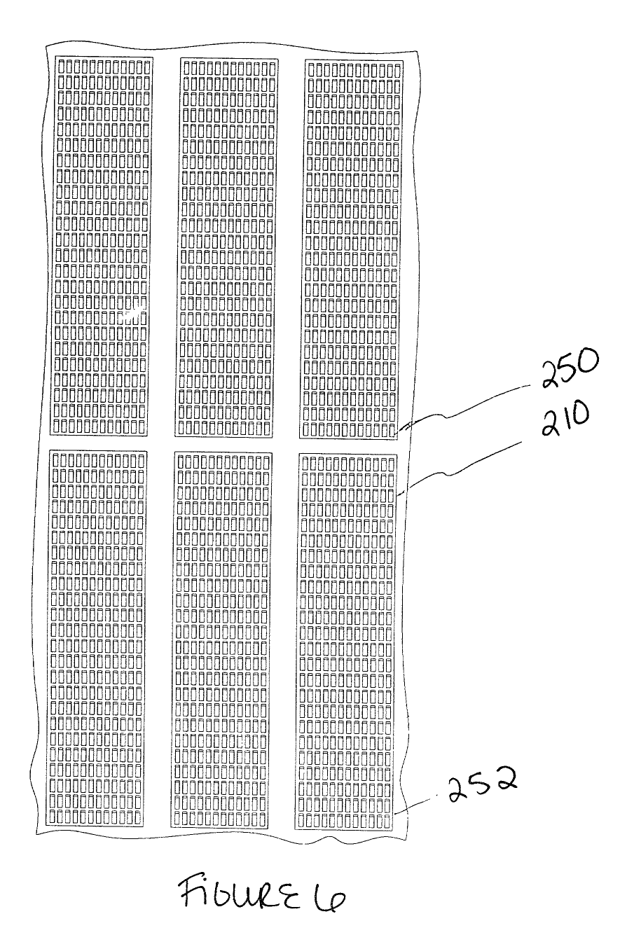

In FIGS. 1-3 only a portion of a panel 10 which may be incorporated into a window is illustrated. Referring to FIG. 4, the construction of such a window 100, which is in this case of a double-glazed window, is illustrated. It is also contemplated that, in accordance with the invention, triple glazed windows may also be fabricated, through the addition of an additional layer of glass on either side of the double-glazed window structure illustrated in schematic form in FIG. 4.

In the illustrated embodiment, the window comprises two layers. The first layer is a light-gating panel 110, which is the equivalent of the panel 10 illustrated in FIGS. 1-3. An insulating body of air 140 is contained between panel 110 and the second layer of glass 142. Both panel 110 and layer of glass 142 are supported within a frame 144. Frame 144 includes appropriate support structure 146 for supporting panel 110 within frame 144 and additional support structure 148 for supporting layer of glass 142 within frame 144. Support structures 146 and 148 may be of any conventional design including plastic molding, glazing triangles and glazing compound, milled woodwork, or the like.

Referring back to FIG. 1, it is noted that each of the rollouts rolls out along its width. This has the advantage that its reaction time is relatively quick, and that a relatively small number of cells need to be fabricated. This also results in minimizing the amount of permanently closed and ungated space. In accordance with the invention, however, it is also possible for the light-gating cells to roll out along their length, as illustrated in the panel 210 depicted in FIG. 5. Here, the inventive panel 210 takes the form of a matrix of individual rollouts 224, which roll out along their length.

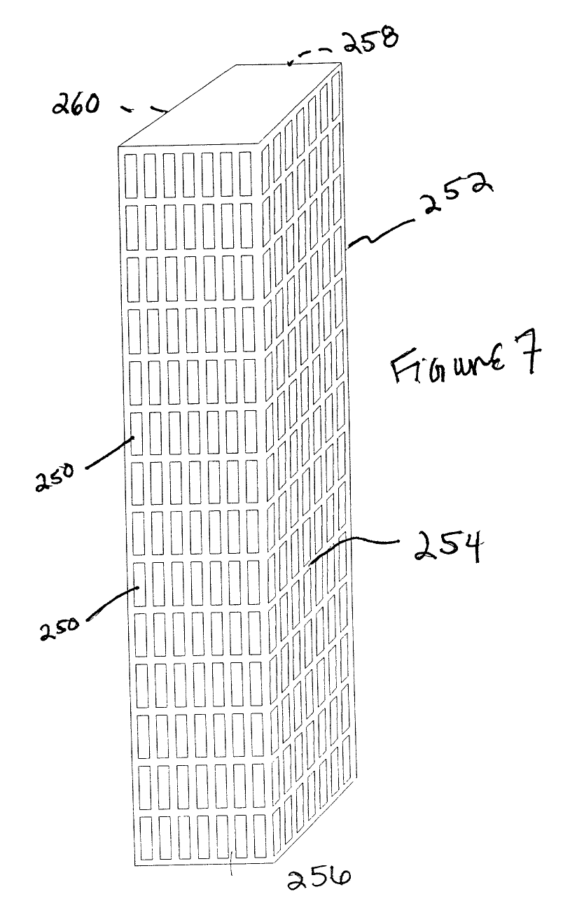

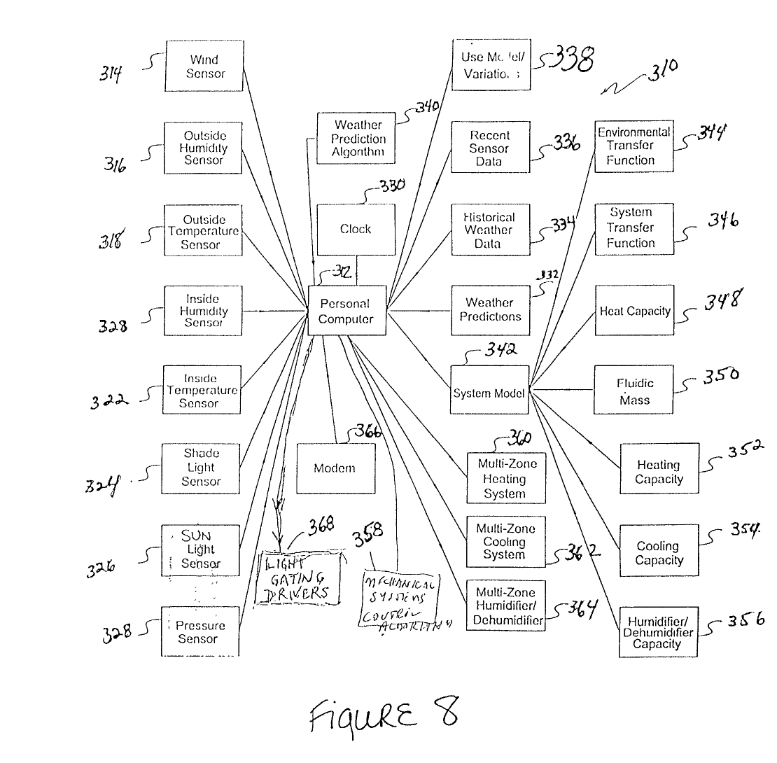

In accordance with the invention, panels, such as panels 210 incorporated in windows 250, may be incorporated into a building 252, a portion of which is illustrated in FIG. 6. The result is building 252 as illustrated in FIG. 7. In accordance with the invention it is noted that building 252 has a plurality of sides, for example, a southern side 254, a western side 256, and eastern side 258, and a northern side 260. This is significant because the given building may experience different environmental conditions on different sides.

These differences may be differences in environmental factors such as temperature, sunlight, windspeed, and humidity.

In addition, different sides of building will have different reactive characteristics in the form of differences in such factors as insulation, leakiness, percentage of area that comprises windows, shape (which may have a significant effect on windspeed against the surface of the building affecting such factors as the effect of leakiness, thermal conduction, and the like).

The reactive characteristics of the building may be used to generate a model of environmental control characteristics of the building. Using this model, it is possible to predict the combined result of environmental factors and operation of the various environmental control systems in the building, including such mechanical systems as heating, cooling, humidifier systems and dehumidifier systems.

In accordance with the present invention, a building, such as building 252 is provided with a plurality of windows 250 constructed in accordance with the present invention whereby electrical actuation of the same may be used to gate light passing through the windows, in accordance with the method and apparatus described above in connection with FIGS. 1 through 6.

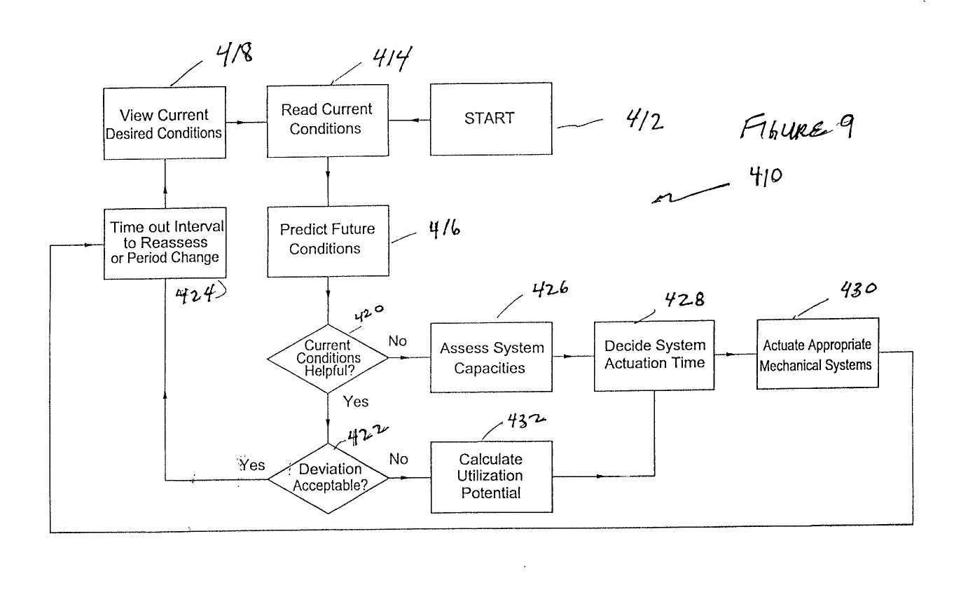

In accordance with the present invention, the optical opening and optical closing of the light-gating windows is controlled by a control system 310 illustrated in FIG. 8. At the heart of the control system is a personal computer 312. Alternatively, in place of personal computer 312, one may employ a dedicated microprocessor with the system control program burned therein.

Personal computer 312 is responsive to a plurality of input systems. These input systems provide the system with real-time indications of various environmental factors, and comprise a plurality of sensors, including, a wind sensor 314, an outside humidity sensor 316, an outside temperature sensor 318, an inside humidity sensor 320, an inside temperature sensor 322, a shade light sensor 324 which measures the intensity of light generally emitted by the sky to areas which are otherwise in shadow, thus giving a reading on sky light intensity, the sunlight intensity sensor 326, and a pressure sensor 328. These sensors provide personal computer 312 with the means to assess the present situation, and respond thereto to operate the system in the most efficient manner within predefined acceptable inside environmental values for temperature, humidity, direct sunlight, and so forth, as will be described more fully below.

Personal computer 312 also has the capacity to make decisions based upon the time of day, the season of the year (and the particular day) and this capacity is provided by a clock 330 which provides the personal computer 312 with day and time information.

Accordingly, personal computer 312 is provided with a number of databases which enable it to provide its environmental system control function. In particular, personal computer 312 has a database which includes long-term weather predictions 332. These long-term weather predictions are the product of actual weather experience sensed by sensors 314-328 and long-term prediction information input into the system on a periodic basis. The system is also provided with historical weather data 334 which enables it to assess possible ranges of environmental factors and temper its predictions based on the same.

Recent sensor data 336 is also input into the system and resident in a database.

The computer has a database which comprises recent sensor data collected by sensors 314-328 which are used by the system to predict future weather based on the various items of information available to system 310.

In addition to the above, the system has in storage user preferences, in terms of desired variations for different days of the week, times of the day and the like which are maintained in a separate database 338.

With reference to all of the above information, the system is programmed to consult a weather prediction algorithm 340.

The user selections in database 338 and the other information input into the system are used to determine what operation of the mechanical systems is required because the desired environmental changes. This is done by testing the same against a system model 342 which includes the various characteristics of the building which is to be heated, cooled, humidified and/or dehumidified. In particular, system model 342 includes a number of sub-databases, including the building's environmental transfer function 344 (the building's reaction to various environmental factors), the system transfer function 346 (the building's reaction to various inputs from its mechanical systems), the capacity of the building 348, the fluidic mass of the air inside the building 350, the heating capacity of the building's heating systems 352, the cooling capacity of the systems cooling systems 354 and the capacity of the building's humidifier/dehumidifier systems 356.

In response to all of the above sensors and databases, and the system's weather prediction algorithm, clock 330 and the mechanical systems control algorithm 358, personal computer 312 provides various control signals to turn various parts of a multi-zone heating system 360 on and off, as well as to control operation of a multizoned cooling system 362 and a multizone humidifier/dehumidifier system 364.

In accordance with the present invention, it is also contemplated that both user preferences, weather prediction information, and the like maybe input into the system from a remote point through use of the Internet and a modem 366.

At the same time, personal computer 312 controls the operation of light gating drivers 368, which has rollouts in windows such as those windows 250 illustrated in FIG. 7, by applying voltage between the rollout and the electrical substrate to cause the rollout to unfurl and block the entry of light into the system.

In accordance of the present invention, it is generally contemplated that during the summertime, and at other times when it is decided to exclude heat from the building during the day, light will be blocked from entering the building, thus reducing the heat load on the cooling system, or making cooling unnecessary. On the other hand, during the night, depending upon the temperature, the rollouts will be actuated, resulting in the windows allowing the passage of light, thus allowing radiant energy to escape from the building through the windows into the darkness of space which reduces the need for cooling. However, if nights in the area are relatively cold, for example as will be the case in San Francisco during the summer, the windows may be optically shuttered during the night to prevent the escape of heat.

Also in accordance with the present invention, desired user ranges may be ignored in the interests of long-term savings. For example, if a relatively cold night is expected during the summer, the system may be allowed to overheat the building during the day in the interest of comfort during the night without the intervention of a heating system.

Conversely, the system may warn inhabitants of the building that the night will be relatively cold and to use appropriate bedding. In this case, the building is allowed to become relatively cold at night, in the interest of being cooler during the day.

Also in accordance with present invention, the mechanical systems are broken up into various sounds based on usage, such as bedrooms and living rooms. In accordance with a preferred embodiment of the invention, bedrooms could be allowed to become overheated at night, while the living room and kitchen of a home could be allowed to become cold at night, insofar as only the bedroom is likely to be used during the night, and the Living room and kitchen are likely to be used only during the day.

In the event that overcompensation has occurred during the day or during the night, the equalization may be achieved by the system circulating air between the cold and hot areas of the home, thus using heat in the bedroom to heat the living room during the day, or vice versa. Also in accordance with the invention, certain constructional features such as large dark brick walls within a home (for example in a bedroom not used during the day in the summertime in a climate like San Francisco) may be used to receive sunlight and store the same to give off heat during the night by allowing light to pass through the windows and fall on such a brick wall during the day.

Referring to FIG. 9, one aspect of the inventive method for controlling mechanical systems to achieve specified environmental ranges inside a building is illustrated. In particular, implementation of method 410 commences with system activation at step 412. Upon activation of the system, the system then reads current conditions at step 414 using, for example, sensors 314-328 as illustrated in FIG. 8.

After reading current conditions at step for 14, the system uses information in part by modem 366 together with data present in databases 336-332 to drive a weather protection algorithm 340 to predict future environmental conditions outside the building. Such prediction is done at step 416 and is done with reference to desired user selections for temperature, humidity, etc. which are input at step 418.

The system then proceeds at step 420 to make a determination as toward whether the current conditions in the house will tend to be corrected naturally by outside variations in temperature, windspeed, etc. based on current conditions and/or predicted conditions, and/or the predicted pattern of weather variation over time. Thus, if it is somewhat hot in the building, and it is at the end of the day, and cold weather is expected in the building at night, and it is expected that the building will be occupied during the night, or more precisely that use of the building overnight dictates a sufficient level of warmth for comfort, the system may decide to tolerate the temporary overheated situation in the interest of reducing fuel consumption in the evening.

More particularly, the system at step 420 determines that, in fact, current conditions are helpful inasmuch as current conditions will tend to be corrected by changes in weather in the immediately following few hours, and then it will proceed to step 422. This determination is based, in part, on the system model 342 illustrated in FIG. 8.

At step 420 to the system overtime in weather the deviation between desired range and the temporary overheated condition (or any other less than ideal condition) is within acceptable range of deviation, or whether it is outside an acceptable range of deviation, in which case other measures are taken.

Accordingly, in the case where the system determines at step 422 that the deviation is acceptable, it proceeds to step 424 where the system simply waits until temperature controls dictate a change in desired conditions, on account of user inputs, at which point the process proceeds back through steps 418 and 414.

If, on the other hand, at step 420 the system determines that current conditions are not helpful, that is, expected changes in environmental factors will not tend to be corrective of existing conditions, the system proceeds to step 426, where system capacities are determined for making the decision as toward when mechanical systems will be actuated. Such decision is made at step 428. This decision is based, in part, on the system model 342 illustrated in FIG. 8.

The system then proceeds to actuate the heating, cooling, humidifier, or dehumidifier systems, as required at step 430. The system then proceeds to step 424 in which it waits a period of time before reassessing the situation or is triggered to reassess the situation by the change in the period. The term “period” refers to a period for a given temperature setting such as that set on a thermostat, which period corresponds to a particular daily activity such as working, arriving at a place of work, leaving a place of work, sleeping at a place of residence, or the like. In accordance with conventional thermostat settings, such periods are used to control temperature. The same may also be used to control other environmental factors.

In the event that at step 420 it is decided that the deviation, between the temperature which would result from allowing outside environmental conditions to correct environmental conditions within the building, is too great a deviation to result in the desired degree of comfort, the system proceeds to step 432 where it calculates the extent to which existing conditions can be used to help the mechanical systems, and a decision would be made at step 428, based on this information as to when and which systems to activate. This calculation is based, in part, on the system model 342 illustrated in FIG. 8.

Preferably, the rollouts, are arranged in rows or columns presenting an agreeable visual appearance when retracted. Use of thin film metallized polymer for the rollouts can permit the rows or columns of rollouts to have the appearance of thin lines when closely viewed and may, with suitable geometry, be substantially invisible from a distance when retracted, or present minor tinting of the window, like traditional mesh window screens. Preferably, the retracted rollouts cover approximately one percent or less of the area that would be covered when the rollouts are actuated and extended. For example, rollouts of about 2.5 mm squared, may retract to thin elongated coils of about 0.25 mm diameter, or less.

Alternatively, the inventive system may further comprise photo voltaic cells to drive a zone of mirrors to respond to sunlight and provide power, and can also employ photosensors, which may be located in structural support members, to detect sunlight and effectuate changes, such as switching the zones of mirrors, to the system accordingly.

While some illustrative embodiments of the invention have been described above, it is, of course, understood that various modifications will be apparent to those of ordinary skill in the art. Such modifications are within the spirit and scope of the invention, which is limited and defined only by the appended claims.

1. A window for gating light for the purpose of controlling temperature within a building, comprising a light transmissive substrate, a plurality of at least partially reflective rollout members disposed on said substrate, and an electrically conductive at least partially light transmissive conductive member disposed in facing relationship with said reflective rollout members and said substrate, a source of electrical potential for causing said rollout members to rollout, conductors for coupling said source of electrical potential to said rollout members and two said at least partially light transmissive conductive member, said at least partially light transmissive conductive member being electrically insulated from said rollout's.

2. A window as in claim 1, wherein said at least partially light transmissive conductive member is disposed between said rollout and said substrate.

3. A window as in claim 2, wherein said rollouts may be individually rolled out, or rolled out in groups comprising less than all of the rollouts on said window.

4. A building comprising a plurality of windows as recited in claim 3.

5. A building comprising a plurality of windows as recited in claim 1.

6. A building having a plurality of sides, each of said sides having a plurality of windows as recited in claim 1 disposed each side, and for the comprising a control system, said control system operative to vary the passage of light through windows on one side of said building to be different from the passage of light through windows on other sides of said building.

7. A building as in claim 5, through the comprising a control system, said control system comprising:
a plurality of environmental conditions sensors;
a central processing unit;
a first computer storage medium portion with a weather protection algorithm recorded on said computer storage medium;
a second computer storage medium portion with user desired internal building environmental conditions recorded thereon;
a third computer storage medium portion with weather prediction information stored thereon;
a fourth computer storage medium portion with a system model of the building and its heating and cooling characteristic stored thereon;
switches coupled to said central processing unit for controlling heating and/or cooling and/or humidifier/dehumidifier systems; and
a plurality of drivers for driving rollouts on said windows.

8. A control system, said control system comprising:
a plurality of environmental conditions sensors;
a central processing unit;
a first computer storage medium portion with a weather protection algorithm recorded on said computer storage medium;
a second computer storage medium portion with user desired internal building environmental conditions recorded thereon;
a third computer storage medium portion with weather prediction information stored thereon;
a fourth computer storage medium portion with a system model of the building and its heating and cooling characteristic stored thereon;
switches coupled to said central processing unit for controlling heating and/or cooling and/or humidifier/dehumidifier systems; and
a plurality of drivers for driving rollouts on said windows.

9. A control system as in claim 8 wherein said sensors comprise an outside temperature sensor and an inside temperature sensor.

10. A control system as in claim 9, wherein said sensors further comprise an outside windspeed sensor.

11. A control system as in claim 10, wherein said sensors further comprise outside humidity sensor, and inside humidity sensor, a shade light sensor, a sunlight sensor, and a pressure sensor.

12. A method for controlling and environmental system in the building, comprising the steps of:
reading current conditions within a building an outside a building;
predicting future outside environmental conditions;
determining whether current conditions within a building are helpful to accommodating future changes, in the outside environment of the building; in the event that such conditions are deemed helpful processing system capacities and deciding upon a system actually should time and actuating appropriate mechanical systems in response to such determination;
implementing a timeout interval before actuation of the system or actuating the system in response to a period change within certain user set input conditions;
in the event that conditions are found helpful, determining whether the deviation caused by using said conditions is helpful and in the event that it is not helpful advancing said timeout interval;
in the event that conditions are not found helpful calculating utilization potential, deciding upon system actually should time and actuating mechanical systems after which the system is advanced to said timeout interval.
